(19) United States
(12) Patent Application Publication
(10) Pub. No.: US 2019/0385976 A1
(43) Pub. Date: Dec. 19, 2019

(54) A NARROW-BORDER DISPLAY PANEL AND A MANUFACTURING METHOD THEREOF

(71) Applicant: Wuhan China Star Optoelectronics Technology Co., Ltd., Wuhan, Hubei (CN)

(72) Inventor: Guowei ZHA, Wuhan, Hubei (CN)

(21) Appl. No.: 15/745,102

(22) PCT Filed: Dec. 5, 2017
(86) PCT No.: PCT/CN2017/114533

§ 371 Date: Jan. 15, 2018

(30) Foreign Application Priority Data
Jul. 21, 2017 (CN) 201710602002.1

(51) Int. Cl. H01L 25/065; H01L 23/538; H01L 25/00

(52) U.S. Cl. CPC H01L 25/0652; H01L 25/50; H01L 23/5387

(57) ABSTRACT

The present disclosure provides a narrow-border display panel and a manufacturing method thereof, comprising a display module having a display driving circuit, a gate circuit, and a bonding area where the display driving circuit and the gate circuit being provided; a flexible substrate having a GOA circuit provided on a surface thereof, one side of which being bound to the bonding area and the other side of which being bent so that the GOA circuit being pasted on a back side of the display module; a bendable metal wire provided on the flexible substrate, and one end of a metal wire being bound to the bonding area connecting to the display driving circuit and the gate circuit, and the other end of the metal wire connecting to the GOA circuit, This disclosure saves a space on the side of the display module and reduces a width of the display panel.

### RELATED APPLICATIONS

The present application is a National Phase of International Application Number PCT/CN2017/114533, filed Dec. 5, 2017, and claims the priority of China Application No. 201710602002.1, filed Jul. 21, 2017.

### FIELD OF THE DISCLOSURE

The disclosure relates to a display technical field, and more particularly to a narrow-border display panel and a manufacturing method thereof.

### BACKGROUND

With a display module technology constantly updated, small-size panels, which especially 4-7-inch mobile phone panels are gradually moving towards light weight, high screen ratio, ultra-narrow border and even to a borderless development, a conventional structure of a LTPS (Low Temperature Poly-silicon) technology of a panel technology compresses a GOA (Gate Driver on Array) circuit size, applies a IC chip of a TDDI (Touch and Display Driver Integration) and reduces a distance between cables which leads a border be close to a level of 0.7 mm; however, in order to ensure an effective operation of a GOA circuit, a reliability test of a display panel and various signal cables are cut off from each other; especially, a compression of a lateral border is approaching a limit. However, a development of a display technology is always driven by a demand and keeps improving, and the demand of a narrow-border display panel significantly improves a visual impact of the display from a standpoint of increasing screen ratio.

At present, from a narrow-border strategy on the market, comprising a Nubia (Nubian mobile phone) Z series uses a thick arc structure to form a narrow-border illusion of a visual borderless technology, or technologies that may be used in the future to hide a border by flexible means, all fall into a category of virtual narrow-border technology from a technical point of view. How to further compress the lateral border of the display panel and ensure the reliability of the display remains a big challenge.

### SUMMARY

In order to solve an above technical problem, a present disclosure provides a narrow-border display panel and a manufacturing method thereof, which saves a space required for a GOA circuit on a lateral side of a display module.

The present disclosure provides the narrow-border display panel, comprising:

The display module comprises a display driving circuit, a gate circuit, and a bonding area where the display driving circuit and the gate circuit are provided;

A flexible substrate has the GOA circuit provided on a surface thereof, one side of the flexible substrate is bound to the bonding area and the other side of the flexible substrate is bent so that the GOA circuit is pasted on a back side of the display module;

Providing a bendable metal wire on the flexible substrate, and one end of a metal wire is bound to the bonding area connecting to the display driving circuit and the gate circuit, and the other end of the metal wire connects to the GOA circuit.

Preferably, the metal wire is a grid-like metal wire, and the metal wire is made of a gold or a copper.

Preferably, a glue made of an acrylate and I or an epoxy is coated on a bonding between the metal wire and the bonding area.

Preferably, the display module comprises a TFT array substrate, and a filter locates on an upper layer of the TFT array substrate, and a backlight module locates on a lower layer of the TFT array substrate, and the display driving circuit, the gate circuit and the bonding area are disposed on the TFT array substrate;

The GOA circuit is pasted on the backlight module.

Preferably, a left side, a right side and a lower side of the filter are within a range of the TFT array substrate.

The present disclosure further provides the narrow-border display panel, comprising:

The display module comprises the display driving circuit, the gate circuit, and the bonding area where the display driving circuit and the gate circuit are provided;

The flexible substrate has the GOA circuit is provided on the surface thereof, one side of the flexible substrate is bound to the bonding area and the other side of the flexible substrate is bent so that the GOA circuit is pasted on the back side of the display module;

Providing the bendable metal wire on the flexible substrate, and one end of the metal wire is bound to the bonding area connecting to the display driving circuit and the gate circuit, and the other end of the metal wire connects to the GOA circuit;

The metal wire is a grid-like metal wire, and the metal wire is made of a gold or a copper;

The glue made of an acrylate and/or an epoxy is coated on a bonding between the metal wire and the bonding area.

Preferably, the display module comprises the TFT array substrate, and the filter locates on the upper layer of the TFT array substrate, and the backlight module locates on the lower layer of the TFT array substrate, and the display driving circuit, the gate circuit and the bonding area are disposed on the TFT array substrate;

The GOA circuit is pasted on the backlight module.

Preferably, the left side, the right side and the lower side of the filter are within the range of the TFT array substrate.

The present disclosure further provides the manufacturing method of the narrow-border display panel, comprising the following steps:

Manufacturing the GOA circuit and the bendable metal wire, one end of the metal wire connects to the GOA circuit;

Providing the bonding area of the display driving circuit and the gate circuit on the display module;

Binding one end of the flexible substrate and the other end of the metal wire to the bonding area;

Bending the other end of the flexible substrate, and pasting the GOA circuit on the back side of the display module.

Preferably, further comprising the follow steps:

The glue made of the acrylate and/or the epoxy is coated on the bonding between the metal wire and the bonding area.

The metal wire is the grid-like metal wire, and the metal wire is made of the gold or the copper.

Preferably; further comprising the follow steps:

Providing the TFT array substrate, and preparing the display driving circuit and the gate circuit on the TFT array substrate;

Providing the filter and cutting a predetermined portion of a first glass substrate on the filter so that a length and a width of the first glass substrate are both smaller than the length and the width of a second glass substrate of the TFT array substrate;

Providing the backlight module, and combining the upper side of the TFT array substrate with the filter, and combining the lower side with the backlight module to obtain the display module.

An implementation of the present disclosure has the following beneficial effects: the display panel of the present disclosure does not need to prepare the GOA circuit on the lateral side of the display module, but prepare the same on the flexible substrate, and then bend the flexible substrate to make it stick to the backside of the display module, and save the space required of the lateral side of the GOA circuit of the display module, so that the lateral size (that is, a width) of the display module can be reduced to form the narrow-border display panel.

### BRIEF DESCRIPTION OF THE DRAWINGS

To describe the technical solutions in the embodiments of the present disclosure or in the prior art more clearly, the following briefly introduces the accompanying figures required for describing the embodiments or the prior art; apparently, the accompanying figures in the following description show merely some embodiments of the present disclosure, and persons of ordinary skill in the art may still derive other figures from these accompanying figures without creative efforts.

FIG. 1 is a side view of a narrow-border display panel provided by the present disclosure.

FIG. 2 is a vertical view of a narrow-border display panel provided by the present disclosure.

FIG. 3 is a bottom view of a narrow-border display panel provided by the present disclosure.

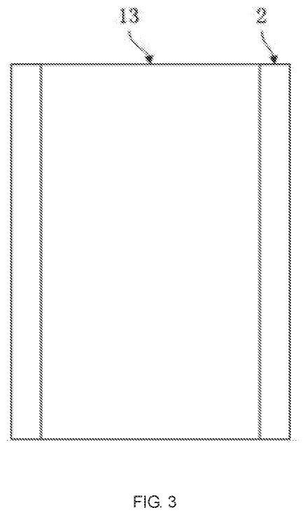

FIG. 4 is a physical structure diagram of a metal wire provided by the present disclosure.

FIG. 5 is a flowchart of a manufacturing method of a narrow-border display panel provided by the present disclosure,

### DETAILED DESCRIPTION OF PREFERRED EMBODIMENTS

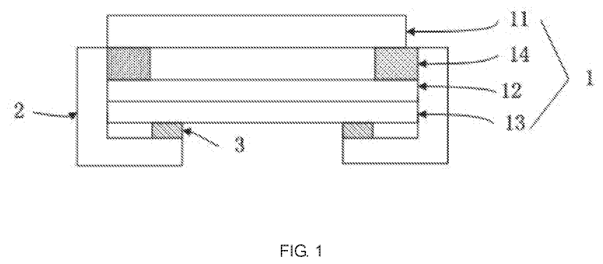

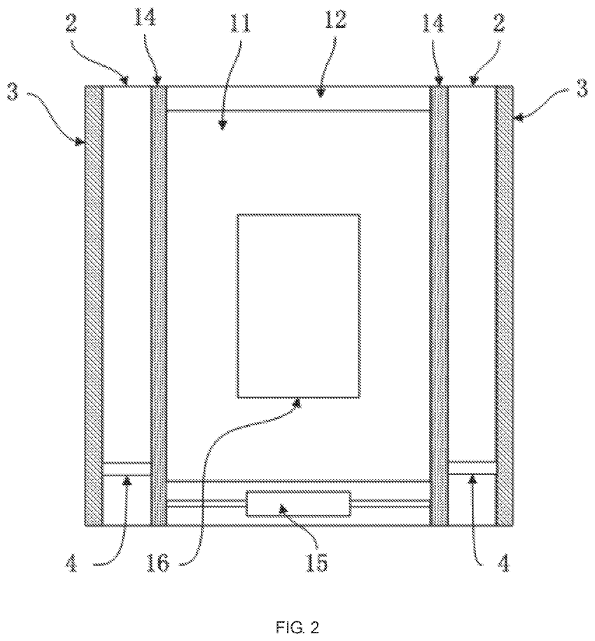

The present disclosure provides a narrow-border display panel, as shown in FIG. 1 and FIG. 2; a display panel comprises: a display module 1, a flexible substrate 2; and a bendable metal wire 4. Wherein, the flexible substrate 2 may be a flexible transparent film made of a PI (polyimide) material.

As shown in FIG. 1 and FIG. 2; the display module 1 comprises a display driving circuit 15 and a gate circuit 16 (that is, the gate circuit); and a bonding area 14 (that is, a bonding pad) of the display driving circuit 15 and the gate circuit 16 is provided, which the bonding area 14 is used for bonding and connecting other circuits, and the other circuits are connected to the display driving circuit 15 and the gate circuit 16.

The flexible substrate 2 has a GOA (Gate Driver on Array) circuit provided on a surface thereof, one side of the flexible substrate is bound to the bonding area and the other side of the flexible substrate is bent so that the GOA circuit is pasted on a back side of the display module. Wherein, the GOA circuit is a gate driving unit and is used on a driving circuit of a horizontal scanning line of the display panel, After the GOA circuit 3 is bound to the bonding area 14, the GOA circuit 3 is connected with the display driving circuit 15 and a scanning driving circuit, and the display driving circuit 15 is configured to output a control signal to the GOA circuit 3, which the GOA circuit 3 controls the gate circuit 16 according to the control signal and realizes a line-by-line driven scanning of a pixel unit by controlling the gate circuit 16.

A thickness of the GOA circuit 3 is small and the GOA circuit is pasted on the back side of the display module 1, which has little influence on an overall display module 1; secondly, when a border of the display module 1 is reduced, that is, a length of the bonding area 14 needs to be reduced, which reduces a bonding force between the display module 1 and the flexible substrate 2; however, when the GOA circuit 3 is pasted on the back side of the display module 1 for fixing, a larger bonding force between the flexible substrate 2 and the display module 1 can be ensured even if the bonding area 14 has a short length.

Providing a metal wire 4 on the flexible substrate 2, and one end of the metal wire is bound to the bonding area 14 which connects to the display driving circuit 15 and the gate circuit 16, and the other end of the metal wire connects to the GOA circuit 3. Specifically, the metal wires 4 are compressed and bound to the bonding area 14 by a bonding technique (Bonding technique, that is, a welding technique between circuits, comprising a ball-welding, a flat-welding, etc.); therefore, a required metal wire 4 needs to be ductile and the metal wire 4 can be pasted on the surface of the flexible substrate 2 to ensure a good bendability and ensure a signal transmission between the GOA circuit 3, the display driving circuit 15 and the gate circuit 16 at the same time.

By narrowing the length of the bonding area 14, the width of the border of the display module can be effectively reduced, that is, the width of the border of the display panel can be reduced; generally, it can be reduced by 200-500 μm.

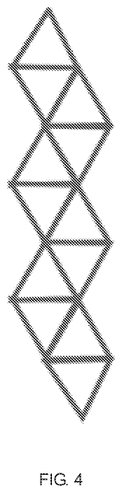

Further, as shown in FIG. 4, the metal wire 4 is a grid-like metal wire 4, and the metal wire 4 is made of a gold or a copper. The fine holes are formed on the metal wire 4 to form a grid-like structure, so that a bendability can be further enhanced, and the metal wire 4 made of a gold or the copper material has better ductility and bending property.

The metal wire 4 may be prepared at the same time as prepared the GOA circuit 3, and the metal wire 4 can be prepared by using any one of a ductile metal layers in the GOA circuit 3 without an additional photomask, and the metal wire 4 is made of preferred gold material, which the metal wire 4 made of the gold material has excellent ductility. At the same time, the grid-like metal wire 4 not only has a good signal conduction function, but also is not easily broken; therefore, it also has the function of preventing disconnection.

Further, the display module 1 comprises a TFT array substrate 12, and a filter 11 locates on an upper layer of the TFT array substrate 12, and a backlight module 13 locates on a lower layer of the TFT array substrate 12, and the display driving circuit 15, the gate circuit 16 and the bonding area 14 are disposed on the TFT array substrate 12. The GOA circuit 3 is pasted on the backlight module 13.

Further, a left side, a right side and a lower side of the filter are within a range of the TFT array substrate. Specifically, the left side, the right side and the lower side of the glass substrate on the filter 11 are all within the range of the glass substrate of the TFT array substrate 12. Because the bonding area 14 is provided on the circuit of the TFT array substrate 12, the bonding area 14 needs to be connected and bound with other circuits, and the left side, the right side, and the lower side of the filter 11 are within the range of the TFT array substrate 12 for the purpose of reserving a space and facilitating subsequent connecting and bonding of other circuits.

Further, coating with a glue made of an acrylate and or an epoxy on the bonding between the metal wire 4 and the bonding area 14. The glue made of the acrylate and/or the epoxy has a high impedance characteristic, when the border of the display panel is reduced, electrostatic ions and a water vapor outside the display panel are easier to enter into the display panel; especially under high temperature environment, the electrostatic ions and the water vapor diffuse faster; therefore, coating with the glue made of the acrylate and I or the epoxy on the bonding between the metal wire 4 and the bonding area 14 can prevent the electrostatic ions or the water vapor outside from entering the display module 1 through gaps between the filter 11 and the TFT array substrate 12 and improving the ability of boiled high temperature and high humidity and other reliability tests of the display module 1.

In practical applications; if the border of the display module 1 is too narrow, the electrostatic ions enter the display module 1 and are relatively easy to accumulate on the surface of the bonding area 14 to form a certain potential difference; therefore; causing some damage to the display module 1, and the glue made of acrylate and/or epoxy has the high impedance characteristic can avoid a large potential difference on the surface of the bonding area 14 and avoid a damage to the display module 1; therefore, an anti-ESD (Electrostatic Discharge) capability of the display module 1 due to being too narrow is also avoided.

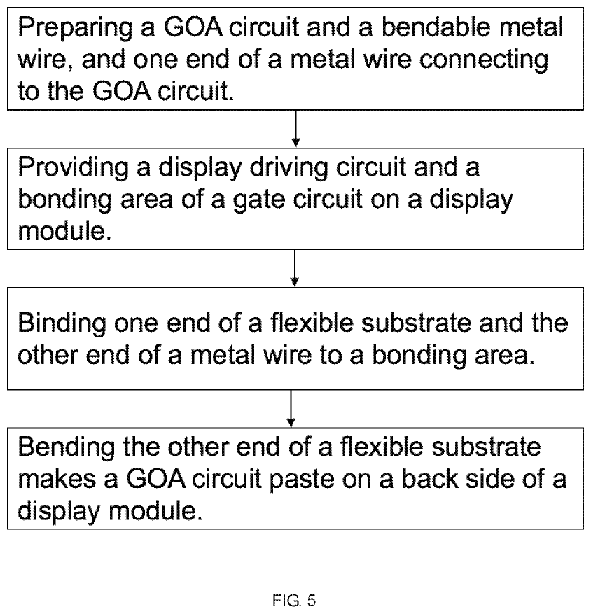

The present disclosure further provides a manufacturing method of the narrow-border display panel, as shown in FIG. 5, the method comprises the following steps:

Manufacturing the GOA circuit 3 and the bendable metal wire 4 on the flexible substrate 2, one end of the metal wire connects to the GOA circuit;

Providing the bonding area 14 of the display driving circuit 15 and the gate circuit 16 on the display module 1;

Binding one end of the flexible substrate 2 and the other end of the metal wire 4 to the bonding area 14;

Bending the other end of the flexible substrate 2, and pasting the GOA circuit 3 on a back side of the display module 1.

Further, the manufacturing method of the narrow-border display panel further comprises the following steps:

Coating with the glue made of the acrylate and/or the epoxy on the bonding between the metal wire 4 and the bonding area 14.

Further, the metal wire 4 is the grid-like metal wire 4, and the metal wire 4 is made of the gold or the copper.

Further, the manufacturing method of the narrow-border display panel further comprises the following steps:

Providing the TFT array substrate 12, and preparing the display driving circuit 15 and the gate circuit 16 on the TFT array substrate 12;

Providing the filter 11 and cutting the predetermined portion of the first glass substrate on the filter 11 so that the length and the width of the first glass substrate are both smaller than the length and the width of a second glass substrate of the TFT array substrate 12;

Providing the backlight module 13, and combining the upper side of the TFT array substrate 12 with the filter 11, and combining the lower side with the backlight module 13 to obtain the display module 1.

To sum up, in the present disclosure, the flexible substrate 2, which the GOA circuit 3 provided on the surface thereof, one side of the flexible substrate 2 is bound to the bonding area 14 and the other side of which is bent so that the GOA circuit 3 is pasted on the back side of the display module 1, and the bendable metal wire 4 provided on the flexible substrate 2, one end of the metal wire 4 is bound to the bonding area 14 which connects to the display driving circuit 15 and the gate circuit 16, and the other end of the metal wire 4 connects to the GOA circuit 3.

Compared with the prior art solutions, the display panel of the present I disclosure does not need to prepare the GOA circuit 3 on the lateral side of the display module 1, but instead prepares the GOA circuit 3 on the flexible substrate 2 and then bends the flexible substrate 2 to paste on the back side of the display module 1, and saves the space required for the GOA circuit 3 on the lateral side of the display module 1 by about 200-500 μm; therefore, the lateral size (that is, width) of the display module 1 can be reduced to form the narrow-border display panel.

The foregoing is the further detailed description of the present disclosure in conjunction with specific preferred embodiments, and it should not be considered that the specific implementation of the present disclosure is limited to these descriptions. For those ordinary skilled in the art to which the present disclosure pertains, a number of simple deductions or replacements may be made without departing from the concept of the present disclosure, and should be considered as belonging to the scope of protection of the present disclosure.

What is claimed is:

1. A narrow-border display panel, comprising:
a display module having a display driving circuit, a gate circuit, and a bonding area where the display driving circuit and the gate circuit being provided;
a flexible substrate having a GOA circuit provided on a surface thereof, one side of the flexible substrate being bound to the bonding area and the other side of the flexible substrate being bent so that the GOA circuit being pasted on a back side of the display module;
a bendable metal wire provided on the flexible substrate, and one end of a metal wire being bound to the bonding area connecting to the display driving circuit and the gate circuit, and the other end of the metal wire connecting to the GOA circuit.

2. The narrow-border display panel according to claim 1, wherein the metal wire is a grid-like metal wire, and the metal wire is made of a gold or a copper.

3. The narrow-border display panel according to claim 1, wherein, a glue made of an acrylate and/or an epoxy is coated on a bonding part between the metal wire and the bonding area.

4. The narrow-border display panel according to claim 1, wherein the display module comprises a TFT array substrate, a filter locates on an upper layer of the TFT array substrate, a backlight module locates on a lower layer of the TFT array substrate, and the display driving circuit, the gate circuit and the bonding area are disposed on the TFT array substrate; and
the GOA circuit is pasted on the backlight module.

5. The narrow-border display panel according to claim 4, wherein a left side, a right side and a lower side of the filter are within a range of the TFT array substrate.

6. A narrow-border display panel, comprising:
a display module having a display driving circuit, a gate circuit, and a bonding area where the display driving circuit and the gate circuit being provided;
a flexible substrate having a GOA circuit being provided on a surface thereof, one side of the flexible substrate being bound to the bonding area and the other side of the flexible substrate being bent so that the GOA circuit being pasted on a back side of the display module;
a bendable metal wire provided on the flexible substrate, and one end of a metal wire being bound to the bonding area connecting to the display driving circuit and the gate circuit, and the other end of the metal wire connecting to the GOA circuit;
the metal wire is a grid-like metal wire, and the metal wire is made of a gold or a copper; and
a glue made of an acrylate and/or an epoxy is coated on a bonding part between the metal wire and the bonding area.

7. The narrow-border display panel according to claim 6, wherein the display module comprises a TFT array substrate, a filter locates on an upper layer of the TFT array substrate, a backlight module locates on a lower layer of the TFT array substrate, and the display driving circuit, the gate circuit and the bonding area are disposed on the TFT array substrate; and
the GOA circuit is pasted on the backlight module.

8. The narrow-border display panel according to claim 7, wherein a left side, a right side and a lower side of the filter are within a range of the TFT array substrate.

9. A manufacturing method of a narrow-border display panel, comprising the following steps:
manufacturing a GOA circuit and a bendable metal wire on a flexible substrate, one end of a metal wire connecting to the GOA circuit;
providing a bonding area of a display driving circuit and a gate circuit on a display module;
binding one end of a flexible substrate and the other end of the metal wire to the bonding area; and
bending the other end of the flexible substrate, and pasting the GOA circuit on a back side of the display module.

10. The manufacturing method of a narrow-border display panel according to claim 9, further comprising the following step:
coating a glue made of an acrylate and/or an epoxy on a bonding between the metal wire and the bonding area.

11. The manufacturing method of a narrow-border display panel according to claim 9, wherein the metal wire is a grid-like metal wire, and the metal wire is made of a gold or a copper.

12. The manufacturing method of a narrow-border display panel according to claim 9, further comprising the following steps:
providing a TFT array substrate, and preparing the display driving circuit and the gate circuit on the TFT array substrate;
providing a filter and cutting a predetermined portion of a first glass substrate on the filter so that a length and a width of the first glass substrate are both smaller than a length and a width of a second glass substrate of the TFT array substrate; and
providing a backlight module, combining an upper side of the TFT array substrate with the filter, and combining a lower side of the TFT array with the backlight module to obtain a display module.
